(19) United States
(12) Patent Application Publication
(10) Pub. No.: US 2025/0241104 A1
(43) Pub. Date: Jul. 24, 2025

(54) DISPLAY DEVICE INCLUDING A FILM BELOW A DISPLAY PANEL, A METHOD OF MANUFACTURING THE DISPLAY DEVICE, AND ELECTRONIC DEVICE INCLUDING THE DISPLAY DEVICE

(71) Applicant: SAMSUNG DISPLAY CO., LTD., YONGIN-SI (KR)

(72) Inventors: SUNGKOOK LEE, Yongin-si (KR); JAEUK CHOI, Yongin-si (KR); KISEO KIM, Yongin-si (KR)

(21) Appl. No.: 19/008,149

(22) Filed: Jan. 2, 2025

(30) Foreign Application Priority Data
Jan. 23, 2024 (KR) 10-2024-0009939

(51) Int. Cl. H10H 29/49; G06F 3/041; H10H 29/01

(52) U.S. Cl. CPC H10H 29/49; G06F 3/0416; H10H 29/012

(57) ABSTRACT

A display device includes a display panel including a display area and a peripheral area at least partially surrounding the display area, a window layer disposed on the display panel and a first film disposed below the display panel and including: a base film and a wire. The wire is disposed inside the base film and has a curved shape.

### CROSS-REFERENCE TO RELATED APPLICATION

This application claims priority under 35 U.S.C. § 119 to Korean Patent Application No. 10-2024-0009939, filed on Jan. 23, 2024, in the Korean Intellectual Property Office, the content of which is incorporated by reference herein in its entirety.

### 1. TECHNICAL FIELD

The present disclosure relates to a display device and, more specifically, to a display device including a film below a display panel, a method of manufacturing the device, and an electronic device including the display device.

### 2. DISCUSSION OF THE RELATED ART

Display devices used in computer monitors, TVs, mobile phones, etc. may include organic light emitting diodes (OLED), which emit light on their own, and liquid crystal displays (LCD), which require a separate light source, such as a backlight, to produce an image.

Display devices have traditionally been used in TVs and computer monitors but more recently, they are being used in a wide variety of personal portable devices. Research is being conducted to develop display devices with larger display areas while reducing their volume and weight.

With recent advancements in display device-related technology, flexible display devices that may be folded or changed into a roll shape are being researched and developed. Moreover, stretchable displays that may be stretched horizontally or vertically are also being developed.

### SUMMARY

A display device according to an embodiment of the present disclosure includes a display panel including a display area and a peripheral area at least partially surrounding the display area, a window layer disposed on the display panel and a first film disposed below the display panel and including: a base film and a wire. The wire is disposed inside the base film and has a curved shape.

A method of manufacturing a display device according to an embodiment of the present disclosure includes providing a display panel including a display area and a peripheral area at least partially surrounding the display area, attaching a first film including a base film and a wire disposed inside the base film below the display panel, the wire having a curved shape, compressing the display panel and the first film into a mold, curing the display panel and the first film and attaching a window layer onto the display panel.

### BRIEF DESCRIPTION OF THE DRAWINGS

The accompanying drawings, which are included to provide a further understanding of the inventive concept and are incorporated in and constitute a part of this specification, illustrate embodiments of the inventive concept together with the description.

FIG. 1 is a perspective view showing a display device according to an embodiment of the present disclosure.

FIG. 2 is a cross-sectional view showing one form of the display device of FIG. 1.

FIG. 3 is a cross-sectional view taken along line I-I′ of FIG. 1.

FIG. 4 is a cross-sectional view showing an example of the display panel of FIG. 3.

FIG. 5 is a plan view showing an example of a first film of FIG. 3 before stretching.

FIG. 6 is a plan view showing an example of a first film of FIG. 3 after stretching. FIG. 7 is a plan view showing an embodiment in which a sensing portion of FIG. 3 is arranged.

FIG. 8 is a plan view showing an embodiment in which the sensing portion of FIG. 3 is arranged.

FIG. 9 is a cross-sectional view showing an embodiment in which the sensing portion of FIG. 3 is connected to a connecting film.

FIGS. 10, 11, 12, 13, 14, 15, and 16 are views illustrating a method of manufacturing a display device according to an embodiment of the present disclosure.

FIG. 17 is a view showing an embodiment of the display device of the present disclosure disposed in a vehicle.

FIG. 18 is a block-diagram showing an electronic device according to an embodiment of the present disclosure.

FIG. 19 is a schematic diagram of the electronic device according to various embodiments of FIG. 18.

### DETAILED DESCRIPTION

Illustrative embodiments of the present disclosure will be more clearly understood from the following detailed description in conjunction with the accompanying drawings.

In this specification, a plane may be defined by a first direction D1 and a second direction D2 that intersects the first direction D1. For example, the second direction D2 may be perpendicular to the first direction D1. In addition, a third direction D3 may be a normal direction of the plane. For example, the third direction D3 may be perpendicular to the plane formed by the first direction D1 and the second direction D2.

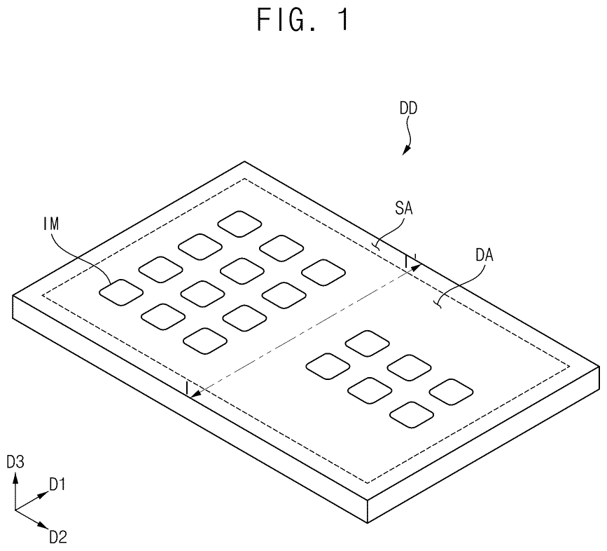

FIG. 1 is a perspective view showing a display device according to an embodiment of the present disclosure.

Referring to FIG. 1, the display device DD may include a display area DA and a peripheral area SA. The display area DA may be at least partially surrounded by the peripheral area SA. As used herein, the phrase “at least partially surrounding” is understood to mean that the surrounding element contacts the surrounded element on at least one side or portion thereof, may contact the surrounded element on two sides, whether those sides are opposite sides or proximate sides, may contact the surrounded element on more than two sides, and may even completely surround the surrounded element.

The display area DA may be an area that may display an image by generating light or adjusting a transmittance of light provided from an external light source. The peripheral area SA may be an area that does not display an image. However, embodiments of the present disclosure are not necessarily limited thereto, and at least a portion of the peripheral area SA may display an image.

The display area DA may display a plurality of images IM. Users may receive information from the display device DD through the plurality of images IM.

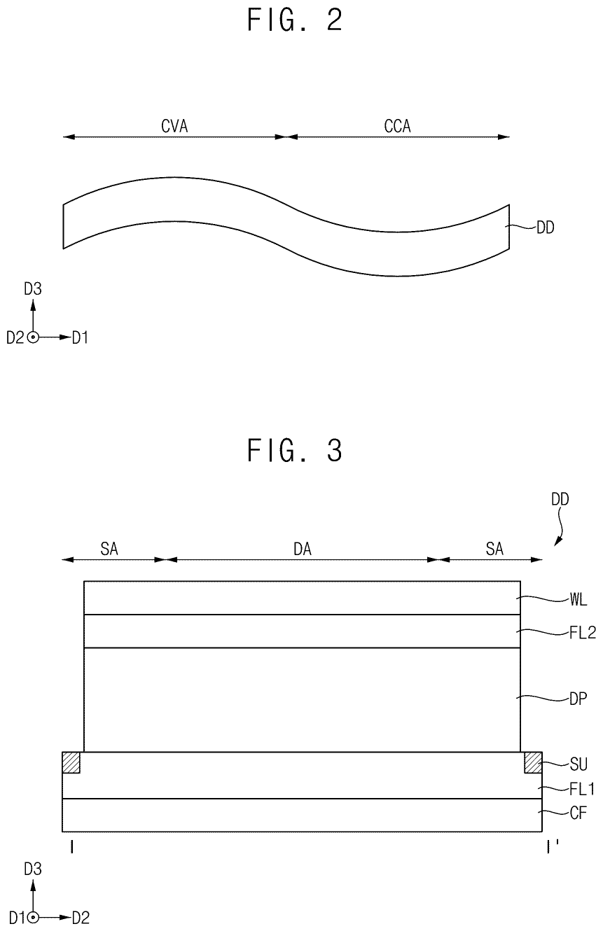

FIG. 2 is a cross-sectional view showing one form of the display device of FIG. 1.

The display device DD may include a convex area CVA and a concave area CCA that are disposed adjacent to each other along the first direction D1. The convex area CVA refers to an area where the display device DD protrudes in the third direction D3, and the concave area CCA refers to an area where the display device DD protrudes in a direction opposite to the third direction D3.

In an embodiment, each of the convex area CVA and the concave area CCA may be provided in one and/or plural numbers along the first direction D1. For example, the display device DD may include two convex areas CVA and one concave area CCA along the first direction D1. Although FIG. 2 shows that the display device DD includes both the convex area CVA and the concave area CCA, the display device DD may include only the convex area CVA and might not include the concave area CCA.

In FIG. 2, the display device DD is shown as including the convex area CVA and the concave area CCA disposed adjacent to each other along the first direction D1. However, the embodiment of the present disclosure is not necessarily limited thereto. For example, the display device DD may include the convex area CVA and the concave area CCA disposed adjacent to each other along the first direction D1 and/or the second direction D2.

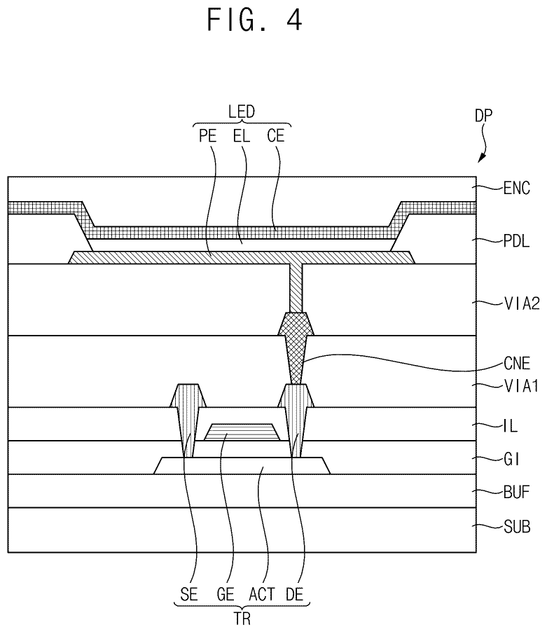

FIG. 3 is a cross-sectional view taken along line I-I′ of FIG. 1.

Referring to FIG. 3, the display device DD may include a cover film CF, a first film FL1, a sensing portion SU, a display panel DP, a second film FL2, and a window layer WL.

The cover film CF may be attached below the display panel DP. The cover film CF may protect the display panel DP from external impacts, foreign substances, etc. For example, the cover film CF may include thermoplastic polyurethane (TPU). However, embodiments of the present disclosure are not necessarily limited thereto.

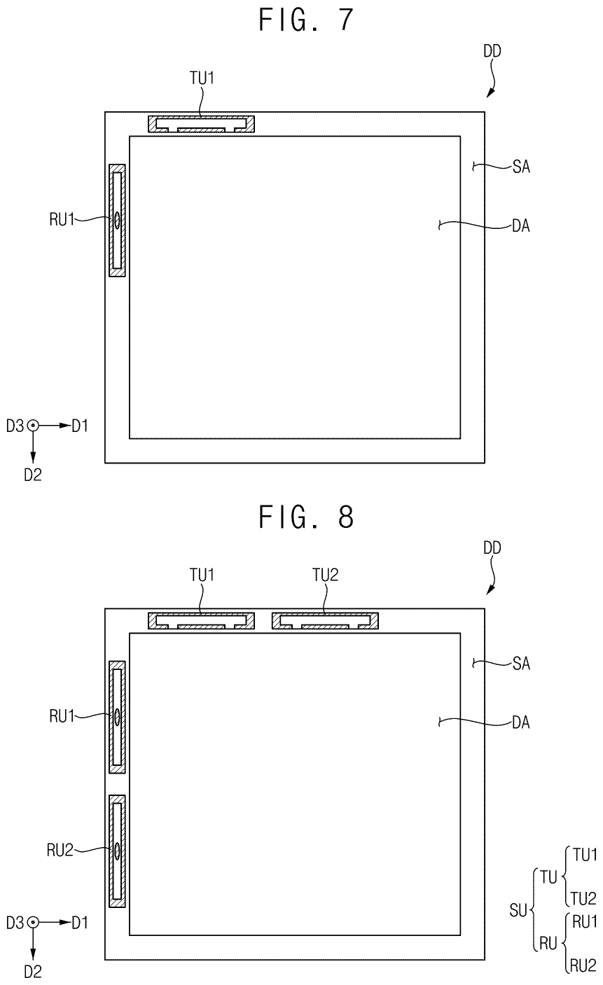

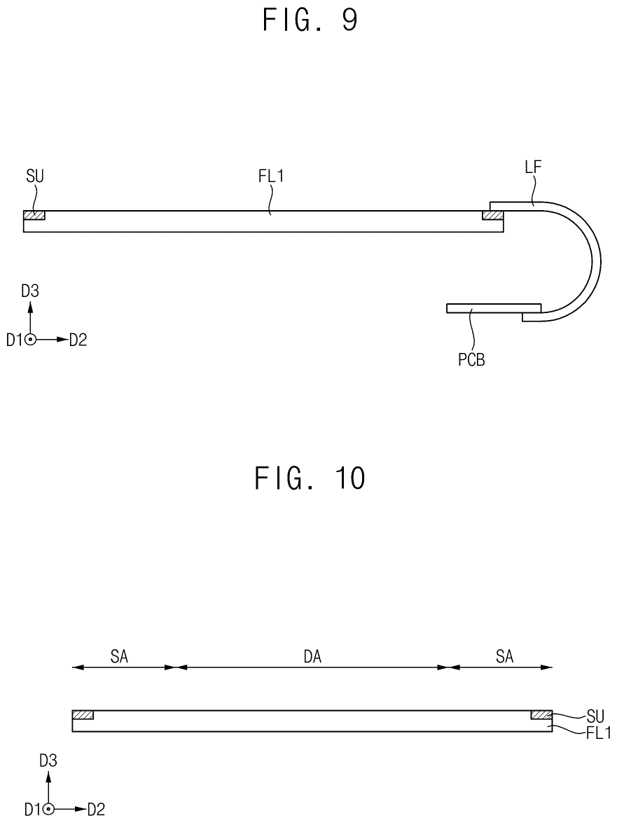

The first film FL1 may be disposed on the cover film CF. For example, the first film FL1 may at least partially cover a top surface of the cover film CF and a bottom surface of the display panel DP. The first film FL1 may protect the display panel DP. For example, the first film FL1 may protect the display panel DP from shock resistance, foreign substances, etc. A planar area of the first film FL1 may be larger than a planar area of the display panel DP. However, embodiments of the present disclosure are not necessarily limited thereto. The first film FL1 will be described in detail later with reference to FIGS. 5 and 6.

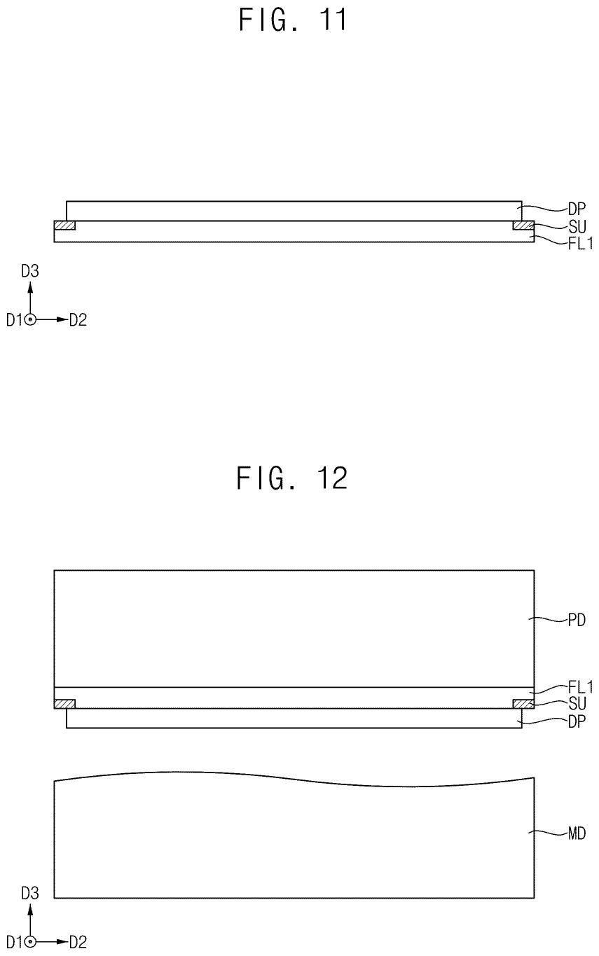

The sensing portion SU may be disposed on the first film FL1. The sensing portion SU may be disposed between the display panel DP and the first film FL1 in a cross-sectional view. For example, the sensing portion SU may overlap the peripheral area SA. The sensing portion SU may detect a user's movement when the user uses the display device DD. For example, the sensing portion SU may detect the user's touch direction, touch pressure, etc. The sensing portion SU will be described in detail later with reference to FIGS. 7 and 8.

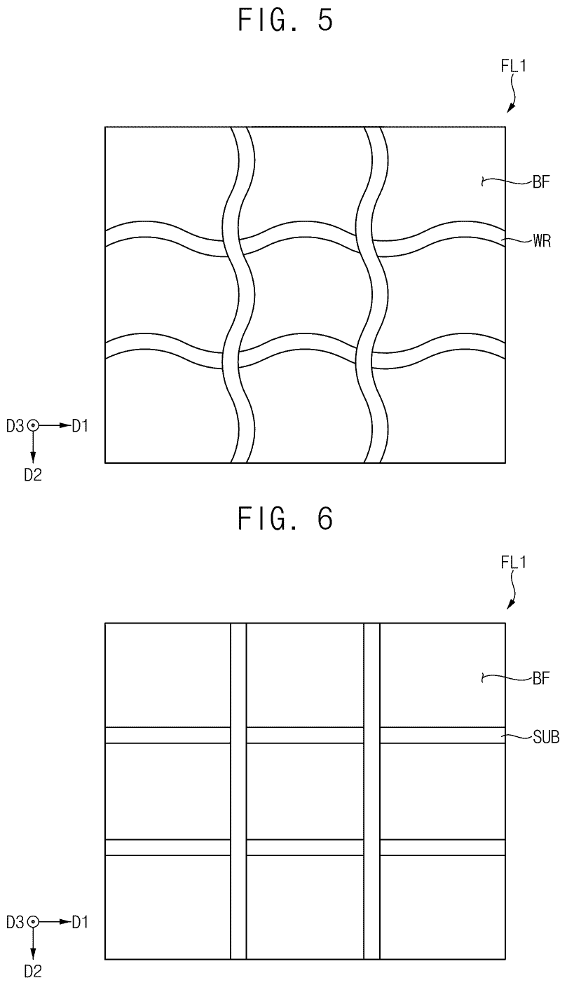

The display panel DP may be disposed on the first film FL1. The display panel DP may emit light according to an applied electrical signal. The display panel DP may include one of an organic light emitting display panel, an inorganic light emitting display panel, and a quantum dot display panel. However, embodiments of the present disclosure are not necessarily limited thereto. The display panel DP will be described in detail later with reference to FIG. 4.

The second film FL2 may be disposed on the display panel DP. For example, the second film FL2 may at least partially cover a top surface of the display panel DP. The second film FL2 may protect the display panel DP. For example, the second film FL2 may protect the display panel DP from shock, foreign substances, etc.

In an embodiment of the present disclosure, the second film FL2 may have stretchability. For example, the second film FL2 may be stretched along the first direction D1, the second direction D2, and/or the third direction D3. For example, the second film FL2 may include polydimethylsiloxane (PDMS). However, embodiments of the present disclosure are not necessarily limited thereto. As the second film FL2 is stretched, the display device DD may be implemented in various shapes which are foldable or stretchable.

The window layer WL may be disposed on the second film FL2. The window layer WL may include a substantially transparent material. For example, the window layer WL may include glass or plastic. However, embodiments of the present disclosure are not necessarily limited thereto.

FIG. 4 is a cross-sectional view showing an example of the display panel of FIG. 3.

Referring to FIGS. 1 and 4, the display panel DP may include a substrate SUB, a buffer layer BUF, a gate insulating layer GI, a transistor TR, an interlayer insulating layer IL, a connection electrode CNE, a first via layer VIA1, a second via layer VIA2, a light emitting diode LED, a pixel defining layer PDL, and an encapsulation layer ENC.

The transistor TR may include an active layer ACT, a gate electrode GE, a source electrode SE, and a drain electrode DE. The light emitting diode LED may include a pixel electrode PE, a light emitting layer EL, and a common electrode CE.

The substrate SUB may include a glass substrate, a metal substrate, a plastic substrate, etc. However, embodiments of the present disclosure are not necessarily limited thereto, and the substrate SUB may be an inorganic layer, an organic layer, or a composite material layer.

The buffer layer BUF may be disposed on the substrate SUB. The buffer layer BUF may prevent impurities such as oxygen and moisture from penetrating into an upper part of the substrate SUB. The buffer layer BUF may include an inorganic insulating material.

The active layer ACT may be disposed on the buffer layer BUF. The active layer ACT may include an oxide semiconductor, a silicon semiconductor, an organic semiconductor, etc. For example, the oxide semiconductor may include indium (In), gallium (Ga), tin (Sn), zirconium (Zr), vanadium (V), hafnium (Hf), cadmium (Cd), germanium (Ge), chromium (Cr), titanium (Ti), and/or zinc (Zn). The silicon semiconductor may include amorphous silicon, polycrystalline silicon, etc. The active layer ACT may include a source region, a drain region, and a channel region disposed between the source region and the drain region.

The gate insulating layer GI may be disposed on the buffer layer BUF. For example, the gate insulating layer GI may at least partially cover the active layer ACT on the buffer layer BUF. The gate insulating layer GI may include an inorganic insulating material. In an embodiment of the present disclosure, the gate insulating layer GI may be formed entirely in the display area DA and the peripheral area SA.

The gate electrode GE may be disposed on the gate insulating layer GI. The gate electrode GE may at least partially overlap the channel region of the active layer ACT. The gate electrode GE may include a conductive material such as a metal, alloy, conductive metal nitride, conductive metal oxide, transparent conductive material. Examples of the conductive material that may be used in the gate electrode GE may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), alloy containing aluminum, alloy containing silver, alloy containing copper, alloy containing molybdenum, aluminum nitride (AlN), tungsten nitride (WN), titanium nitride (TiN), chromium nitride (CrN), tantalum nitride (TaN), strontium ruthenium oxide (SrRuO), zinc oxide (ZnO), indium tin oxide (ITO), tin oxide (SnO), indium oxide (InO), gallium oxide (GaO), indium zinc oxide (IZO), etc. These may be used alone or in combination with each other. Alternatively, the gate electrode GE may have a single-layer structure or a multi-layer structure including a plurality of conductive layers.

The interlayer insulating layer IL may be disposed on the gate electrode GE. For example, the interlayer insulating layer IL may be disposed on the gate insulating layer GI and at least partially cover the gate electrode GE on the gate insulating layer GI. The interlayer insulating layer IL may include an inorganic insulating material.

The source electrode SE and the drain electrode DE may be disposed on the interlayer insulating layer IL. Each of the source electrode SE and the drain electrode DE may be connected to the active layer ACT. For example, the source electrode SE may contact the source region of the active layer ACT, and the drain electrode DE may contact the drain region of the active layer ACT. Each of the source electrode SE and the drain electrode DE may include a conductive material. The active layer ACT, the gate electrode GE, the source electrode SE, and the drain electrode DE may form the transistor TR.

The first via layer VIA1 may be disposed on the source electrode SE and the drain electrode DE. For example, the first via layer VIA1 may be disposed on the interlayer insulating layer IL and at least partially cover the source electrode SE and the drain electrode DE on the interlayer insulating layer IL. The first via layer VIA1 may include an organic insulating material. In an embodiment, the first via layer VIA1 may be formed only in the display area DA and a portion of the peripheral area SA adjacent to the display area DA.

The connection electrode CNE may be disposed on the first via layer VIA1. The connection electrode CNE may transmit a signal transmitted from the transistor TR to the light emitting diode LED. The connection electrode CNE may include metal, alloy, metal nitride, conductive metal oxide, transparent conductive material, etc. These may be used alone or in combination with each other. However, embodiments of the present disclosure are not necessarily limited thereto.

The second via layer VIA2 may be disposed on the connection electrode CNE. For example, the second via layer VIA2 may be disposed on the first via layer VIA1 and cover the connection electrode CNE. The second via layer VIA2 may include substantially a same material as the first via layer VIA1.

The pixel electrode PE may be disposed on the second via layer VIA2. The pixel electrode PE may include a conductive material. The pixel electrode PE may be connected to the drain electrode DE through the connection electrode CNE. Accordingly, the pixel electrode PE may be electrically connected to the transistor TR.

The pixel defining layer PDL may be disposed on the pixel electrode PE. For example, the pixel defining layer PDL may expose at least a portion of the pixel electrode PE. The pixel defining layer PDL may include an inorganic insulating material or an organic insulating material.

The light emitting layer EL may be disposed on the pixel electrode PE. For example, the light emitting layer EL may be disposed within an opening defined by the pixel defining layer PDL. For example, the light emitting layer EL may be at least partially surrounded by the pixel defining layer PDL. The light emitting layer EL may include at least one of organic light emitting material and/or quantum dots. However, embodiments of the present disclosure are not necessarily limited thereto.

The common electrode CE may be disposed on the light emitting layer EL. The common electrode CE may also be disposed on the pixel defining layer PDL. For example, the common electrode CE may be continuously disposed on the light emitting layer EL and the pixel defining layer PDL. The common electrode CE may include a conductive material. The light emitting layer EL may emit light based on voltage difference between the pixel electrode PE and the common electrode CE.

The encapsulation layer ENC may be disposed on the common electrode CE. The encapsulation layer ENC may include at least one inorganic encapsulation layer and at least one organic encapsulation layer. In an embodiment of the present disclosure, the inorganic encapsulation layer and the organic encapsulation layer may be alternately disposed. For example, the organic encapsulation layer may include a cured polymer such as polyacrylate, epoxy resin, silicone resin, etc. For example, the inorganic thin film may include Silicon oxide (SiO₂), silicon nitride (Si₃N₄), silicon carbide (SiC), aluminum oxide (Al₂O₃), tantalum oxide (Ta₂O₅), hafnium oxide (HfO₂), zirconium oxide (ZrO₂), and titanium oxide (TiO₂), etc.

FIG. 5 is a plan view showing an example of a first film of FIG. 3 before stretching. FIG. 6 is a plan view showing an example of a first film of FIG. 3 after stretching. For example, FIG. 5 is a plan view showing a form of the first film FL1 before stretching, and FIG. 6 is a plan view showing a form of the first film FL1 after stretching along the first direction D1 and/or the second direction D2.

Referring to FIGS. 2, 5, and 6, the first film FL1 may include a base film BF and a wire WR.

In an embodiment of the present disclosure, when the first film FL1 is bent, the wire WR may distribute a force concentrated on a bent portion of the first film FL1. For example, as shown in FIG. 2, the first film FL1 may be bent in the convex area CVA and/or the concave area CCA, and when an elongation of the first film FL1 exceeds an elongation limit, destruction may occur in the first film FL1. As the first film FL1 includes the wire WR, when the first film FL1 is bent, the first film FL1 may be evenly stretched over an entire area of the display device DD as the wire WR is stretched together. For example, the wire WR acts as a spring in the first film FL1, so that even when only a portion of the first film FL1 is bent, an entire area of the first film FL1 is stretched evenly.

In an embodiment of the present disclosure, the wire WR may have a curved pattern in a plan view. For example, the wire WR may have an S-shape. The wire WR may be disposed inside the first film FL1. An elongation rate when the wire WR is stretched from the shape of FIG. 5 to the shape of FIG. 6 may be substantially a same as an elongation rate of the base film BF. For example, an elongation rate of the first film FL1 when stretched along the first direction D1 and/or the second direction D2 may be substantially a same as the elongation rate of the wire WR. Accordingly, the curved pattern of the wire WR may be formed based on the elongation of the base film BF.

In an embodiment of the present disclosure, the wire WR may include metal. For example, the wire WR may include molybdenum (Mo), aluminum (Al), chromium (Cr), gold (Au), titanium (Ti), nickel (Ni), neodymium (Nd), copper (Cu), etc. These may be used alone or in combination with each other. However, embodiments of the present disclosure are not necessarily limited thereto.

The base film BF may include a curable film. For example, the base film BF may include a thermosetting film or a UV curable film. For example, the base film BF may include poly caprolactone (PCL) or a curable silicone member. However, embodiments of the present disclosure are not necessarily limited thereto.

As a result, as the first film FL1 includes the wire WR, stress may be distributed rather than concentrated when the display device DD is bent. For example, when the first film FL1 is bent, the wire WR acts as a spring so that stress may be evenly distributed over an entire area of the display device DD. In addition, as the first film FL1 includes the base film BF having curability, the display device DD might not be lifted after being attached to an object (e.g., automobiles, watches, etc.). Accordingly, as a stress applied to the display device is distributed, a stability of the device may be increased, and a lifting phenomenon may be prevented to ensure reliability.

FIG. 7 is a plan view showing an embodiment in which a sensing portion of FIG. 3 is arranged. FIG. 8 is a plan view showing an embodiment in which the sensing portion of FIG. 3 is arranged.

Referring to FIGS. 7 and 8, the sensing portion SU may include a transmission sensing portion TU that transmits a touch driving signal and a reception sensing portion RU that receives a sensing signal. There may be a plurality of transmission sensing portions TU and the reception sensing portions RU. For example, the transmission sensing portion TU may include a first transmission sensing portion TU1 and a second transmission sensing portion TU2. The reception sensing portion RU may include a first reception sensing portion RU1 and a second reception sensing portion RU2. However, embodiments of the present disclosure are not necessarily limited thereto. For example, there may be three or more transmission sensing portions TU and the reception sensing portions RU.

The first and second transmission sensing portions TU1 and TU2 may have a rectangular shape with one first part extending along the first direction D1 in a plan view and two second parts extending along the second direction D2 from the first part. Each of the first and second receiving sensing portions RU1 and RU2 may have a picture frame shape with a circular shape disposed inside the frame shape, in a plan view. For example, the picture frame shape may refer to a shape with four sides surrounding outer corners, with opposite sides being parallel and equal in length. However, the embodiment of the present disclosure is not necessarily limited thereto, and each of the transmission sensing portion TU and the reception sensing portion RU may have various planar shapes.

In an embodiment of the present disclosure, as shown in FIG. 7, the transmission sensing portion TU and the reception sensing portion RU may be disposed in the peripheral area SA. As shown in FIG. 7, the first transmission sensing unit TU1 may be disposed on one side of the peripheral area SA of the display device DD, and the first reception sensing unit RU1 may be disposed on the other side of the first transmission sensing unit TU1. However, embodiments of the present disclosure are not necessarily limited thereto.

In an embodiment, as shown in FIG. 8, the first transmission sensing portion TU1 and the second transmission sensing portion TU2 may be disposed on one side of the peripheral area SA of the display device DD, and the first reception sensing portion RU1 and the second reception sensing portion RU2 may be disposed on the other side different from the first transmission sensing portion TU1 and the second transmission sensing portion TU2. However, embodiments of the present disclosure are not necessarily limited thereto.

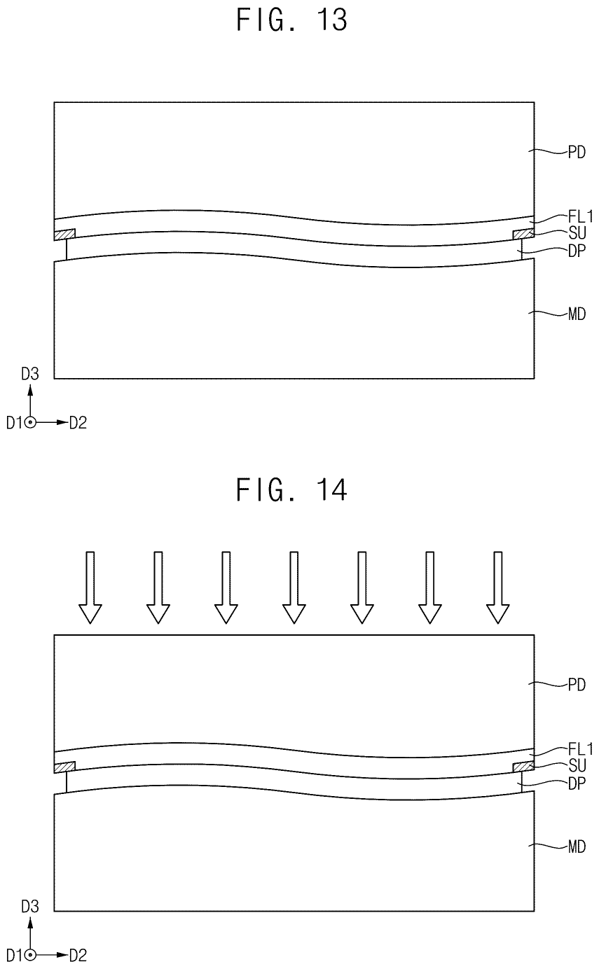

FIG. 9 is a cross-sectional view showing an embodiment of the present disclosure in which the sensing portion of FIG. 3 is connected to a connecting film.

Referring to FIGS. 3 and 9, the display device DD may further include a connection film LF and a printed circuit board PCB.

The sensing portion SU may be connected to the printed circuit board PCB through the connecting film LF. For example, the sensing portion SU may be attached to first end of the connecting film LF, and the printed circuit board PCB may be attached to second end of the connecting film LF opposite to the first end. The printed circuit board PCB may drive the sensing portion SU by applying an electrical signal.

The first end and the second end of the connection film LF may be attached to the sensing portion SU and the printed circuit board PCB through an anisotropic conductive film ACF, respectively. However, embodiments of the present disclosure are not necessarily limited thereto.

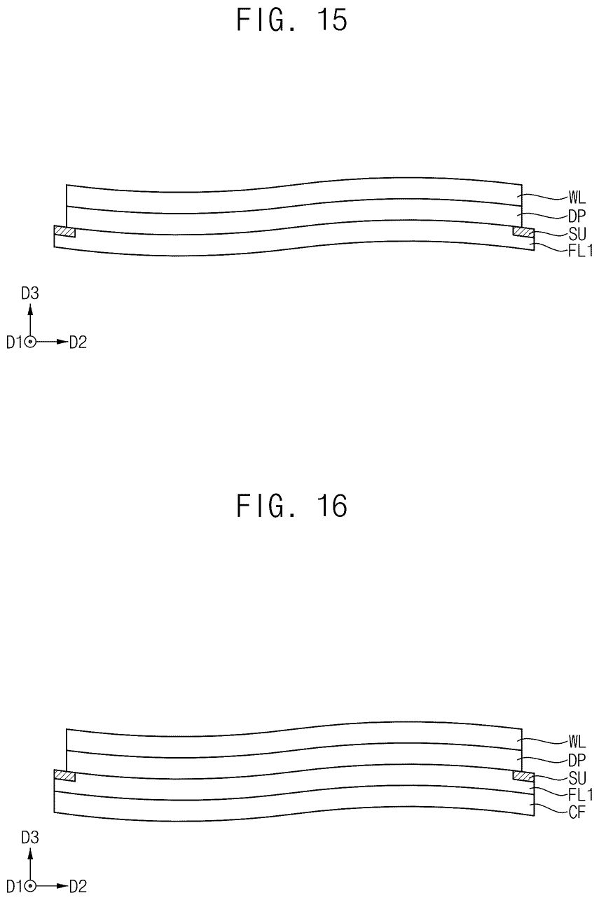

FIGS. 10, 11, 12, 13, 14, 15, and 16 are views illustrating a method of manufacturing a display device according to an embodiment of the present disclosure.

Referring to FIG. 10, the sensing portion SU may be formed on the first film FL1. For example, the sensing portion SU may be formed on the first film FL1 before attaching the first film FL1 to the display panel DP. The sensing portion SU may be formed in the peripheral area SA.

Referring further to FIGS. 3 and 11, the first film FL1 may be attached to one surface of the display panel DP. For example, the first film FL1 may be disposed below the display panel DP. For example, the first film FL1 may be attached to the substrate (e.g., the substrate SUB in FIG. 4) of the display panel DP.

In an embodiment of the present disclosure, the second film FL2 may be further attached to the display panel DP. For example, the second film FL2 may be attached to the encapsulation layer ENC (e.g., the encapsulation layer ENC in FIG. 4) of the display panel DP. The second film FL2 may be attached to the display panel DP using a pressure sensitive adhesive (PSA). However, embodiments of the present disclosure are not necessarily limited thereto.

In an embodiment of the present disclosure, the second film FL2 may be attached to the display panel DP before attaching the first film FL1. For example, after attaching the second film FL2 to the display panel DP, the first film FL1 may be attached to the display panel DP on the other side of a surface to which the second film FL2 is attached. In some embodiments, the second film FL2 may be attached to the display panel DP after attaching the first film FL1. For example, the second film FL2 may be attached to the other side of the surface to which the first film FL1 is attached.

Referring further to FIG. 12, in an embodiment of the present disclosure, the display panel DP and the first film FL1 may be attached to the pad PD. The pad PD may be a soft pad. For example, the pad PD may be a soft pad containing silicon. As the display panel DP and the first film FL1 are attached to the soft pad, the display panel DP and the first film FL1 may be evenly attached to a mold MD without any gaps. As shown in FIG. 2, the mold MD may be an object including the convex area CVA and the concave area CCA. For example, the mold MD may be an object having a concave or convex surface shape in a 3D shape.

Referring further to FIG. 13, the display panel DP and the first film FL1 may be compressed to the mold MD along a direction opposite to the third direction D3. As the display panel DP and the first film FL1 are compressed, a cross-sectional shape of the display panel DP and the first film FL1 may be substantially a same as a shape of the mold MD. For example, shapes of the display panel DP and the first film FL1 may be molded based on a shape of the mold MD.

Referring further to FIG. 14, after the display panel DP and the first film FL1 are compressed to the mold MD, the display panel DP and the first film FL1 may be cured.

In an embodiment of the present disclosure, the first film FL1 may be thermally cured while being compressed against the mold MD. For example, the first film FL1 may be cured along the shape of the mold MD while being compressed against the mold MD. For example, when the base film (e.g., base film BF in FIG. 5) of the first film FL1 is poly caprolactone (PCL), the first film FL1 may be thermally cured below 60 degrees. In some embodiments, the first film FL1 may be UV cured while being compressed into the mold MD. For example, the first film FL1 may be cured along a shape of the mold MD by ultraviolet rays. However, embodiments of the present disclosure are not necessarily limited thereto.

As the first film FL1 is cured in accordance with a shape of the mold MD, a shape of the display panel DP and the first film FL1 may remain similar to a shape of the mold MD even after removing the pad PD. Accordingly, a lifting phenomenon may be prevented even when the display panel DP and the first film FL1 are attached to a curved part of an object (e.g., a car, a watch, etc.).

Referring further to FIG. 15, the window layer WL may be attached to the display panel DP. For example, as shown in FIG. 14, the window layer WL may have a curved shape similar to a shape of a top surface of the display panel DP. The window layer WL may be attached to the display panel DP using an optically clear adhesive film, an optically clear adhesive resin. As described with reference to FIG. 11, the second film (e.g., the second film FL2 in FIG. 3) may be formed between the window layer WL and the display panel DP in a cross-sectional view.

Referring further to FIG. 16, after the window layer WL is formed on the display panel DP, the cover film CF may be formed below the first film FL1. The cover film CF may protect the display device (e.g., the display device DD in FIG. 1) from external shock.

According to the manufacturing method shown in FIGS. 10, 11, 12, 13, 14, 15, and 16, the window layer WL, the display panel DP, the first film FL1, and the cover film (e.g., the cover film CF of FIG. 3) may be sequentially attached and may form the display device (e.g., the display device DD of FIG. 3).

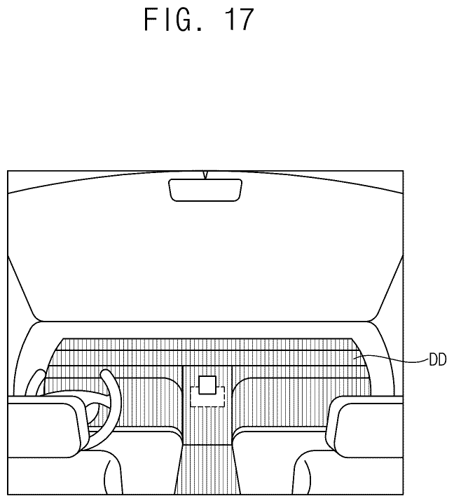

FIG. 17 is a view showing an embodiment of the display device of the present disclosure disposed in a vehicle. For example, the display device DD of FIG. 17 may correspond to the display device DD of FIG. 3.

Referring to FIGS. 2, 3, and 17, the display device DD may include the convex area CVA and the concave area CCA. Accordingly, the display device DD may have a curved shape so that the display device DD may be attached to an object such as a car. For example, the display device DD may be attached to the center fascia, windshield, and/or instrument panel of the vehicle and provide visual information to the user. However, embodiments of the present disclosure are not necessarily limited thereto. The display device DD may be used not only in the automobile but also in watches, laptops, mobile phones, and wearable devices.

The present disclosure may be applied to the display device and the electronic device including a same. For example, the present disclosure may be applied to high-resolution smartphones, mobile phones, smart pads, smart watches, tablet PCs, vehicle navigation systems, televisions, computer monitors, laptops, etc.

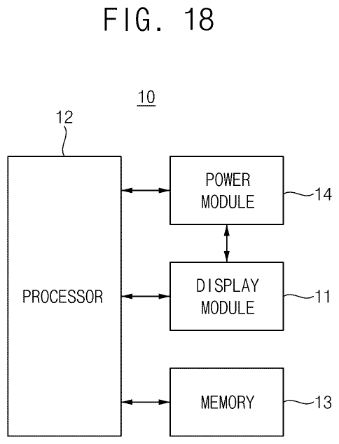

FIG. 18 is a block-diagram showing an electronic device according to an embodiment of the present disclosure.

Referring to FIGS. 1 and 18, the display device DD according to the embodiments may be applied to various electronic devices 10. The electronic device 10 according to an embodiment may include the display device DD, and may further include a module or device having additional functions in addition to the display device DD.

The electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data information necessary for the operation of the processor 12 or the display module 11. When the processor 12 executes an application stored in the memory 13, an image data signal and/or an input control signal is transmitted to the display module 11, and the display module 11 may process the received signal and output image information through a display screen.

The power module 14 may include a power supply module such as a power adapter or a battery device, and a power conversion module that converts the power supplied by the power supply module to generate power necessary for the operation of the electronic device 10.

At least one of the components of the electronic device 10 described above may be included in the display device DD according to the embodiments described above. In addition, some of the individual modules functionally included in one module may be included in the display device DD, and other parts may be provided separately from the display device DD. For example, the display device DD may include the display module 11, and the processor 12, the memory 13, and the power module 14 may be provided in a form of another device within the electronic device 10 other than the display device DD.

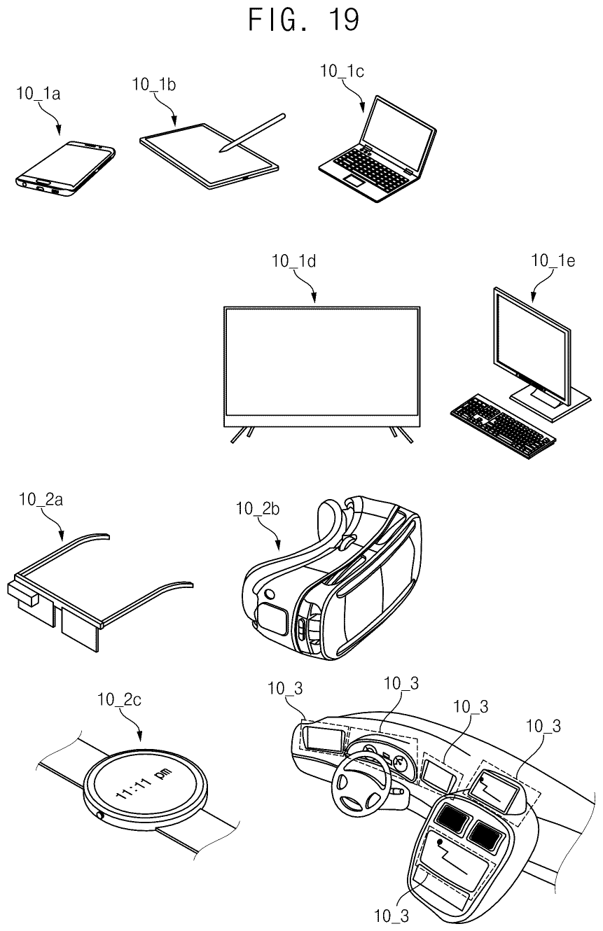

FIG. 19 is a schematic diagram of the electronic device according to various embodiments of FIG. 18.

Referring to FIGS. 18 and 19, various electronic devices 10 to which the display device DD according to the embodiments is applied may include not only image display electronic devices such as a smart phone 10_1a, a tablet PC 10_1b, a laptop 10_1c, a TV 10_1d, a desk monitor 10_1e, but also wearable electronic devices including display modules such as smart glasses 10_2a, a head-mounted display 10_2b, a smart watch 10_2c, etc. and vehicle electronic devices 10_3 including display modules such as a CID (Center Information Display) disclosure on a dashboard, center fascia, or dashboard of a car, and a room mirror display.

However, this is exemplary, and the electronic devices 10 according to the embodiments of the present disclosure are not necessarily limited thereto. For example, the electronic device 10 may be implemented as a mobile phone, a video phone, a smart pad, a smart watch, a tablet PC, a vehicle display, a computer monitor, a notebook computer, a head-mounted display device, etc. In addition, the electronic device 10 may be a television, a monitor, a notebook computer, or a tablet. In addition, the electronic device 10 may be an automobile

While the disclosure has been particularly shown and described with reference to embodiments thereof, it will be understood by those of ordinary skill in the art that various changes in form and details may be made therein without departing from the spirit or scope of the disclosure.

What is claimed is:

1. A display device, comprising:
a display panel including a display area and a peripheral area at least partially surrounding the display area;
a window layer disposed on the display panel; and
a first film disposed below the display panel and including:
a base film; and
a wire,
wherein the wire is disposed inside the base film and has a curved shape.

2. The display device of claim 1, wherein the wire includes metal.

3. The display device of claim 1, wherein the first film includes a thermosetting film or an ultraviolet (UV) curable film.

4. The display device of claim 1, wherein the base film includes poly caprolactone (PCL).

5. The display device of claim 1, wherein an elongation rate of the first film is a same as an elongation rate of the display panel.

6. The display device of claim 1, further comprising:
a sensing portion disposed between the display panel and the first film, in a cross-sectional view.

7. The display device of claim 6, wherein the sensing portion overlaps the peripheral area.

8. The display device of claim 6, wherein the sensing portion includes at least one transmission sensing portion that is configured to transmit a touch driving signal and at least one reception sensing portion that is configured to receive a sensing signal.

9. The display device of claim 6, further comprising:
a connecting film with a first end that is attached to the sensing portion; and
a printed circuit board attached to a second end of the connecting film that is opposite to the first end.

10. The display device of claim 1, further comprising:
a second film disposed on the display panel, the second film being streachable.

11. The display device of claim 10, wherein the second film includes polydimethylsiloxane (PDMS).

12. A method of manufacturing a display device, the method comprising:
providing a display panel including a display area and a peripheral area at least partially surrounding the display area;
attaching a first film including a base film and a wire disposed inside the base film below the display panel, the wire having a curved shape;
compressing the display panel and the first film into a mold;
curing the display panel and the first film; and
attaching a window layer onto the display panel.

13. The method of claim 12, further comprising:
attaching a second film onto the display panel, after attaching the first film and before compressing the first film.

14. The method of claim 12, further comprising:
attaching a second film onto the display panel, after providing the display panel and before attaching the first film.

15. The method of claim 12, wherein the first film is cured using heat.

16. The method of claim 12, wherein the first film is cured using ultraviolet rays.

17. The method of claim 12, further comprising:
attaching a cover film below the first film after attaching the window layer.

18. The method of claim 12, further comprising:
forming a sensing portion on the first film after providing the display panel and before attaching the first film.

19. The method of claim 18, wherein the sensing portion is formed in the peripheral area.

20. The method of claim 12, wherein in the compressing the display panel and the first film into the mold, and
wherein the display panel and the first film are compressed together with a soft pad.

21. An electronic device comprising:
a display device; and
a processor configured to drive the display device, and
wherein the display device includes:
a display panel including a display area and a peripheral area at least partially surrounding the display area;
a window layer disposed on the display panel; and
a first film disposed below the display panel and including:
a base film; and
a wire,
wherein the wire is disposed inside the base film and has a curved shape.
